(19) United States
(12) Patent Application Publication
(10) Pub. No.: US 2010/0097855 A1
(43) Pub. Date: Apr. 22, 2010

(54) Non-volatilization semiconductor memory and the write-in method thereof

(76) Inventor: MATHIAS BAYLE, TOKYO (JP)

Correspondence Address: Muncy, Geissler, Olds & Lowe, PLLC, P.O. BOX 1364, FAIRFAX, VA, 22038-1364, US

(21) Appl. No.: 12/582,504

(22) Filed: Oct. 20, 2009

(30) Foreign Application Priority Data
Oct. 21, 2008 (JP) JP2008-270937

(51) Int. Cl. G11C 16/04

(52) U.S. Cl. 365/185.03; 365/185.19; 365/185.24; 365/185.22

(57) ABSTRACT

Task: to decrease the number of times of the verifying process and shorten the time to program.

Means for Solving the Problems: In a non-volatile semiconductor memory device, comprising: a non-volatile memory array, which stores multi-valued states by setting a plurality of different threshold voltages to correspond to a plurality of states to each memory cell; and a control circuit, which controls programming to the memory cell array, when increasing the programming voltage from a predetermined programming start voltage by a predetermined voltage increment gradually and verifying it at the same time for programming the memory cell, the control circuit determines and sets the programming start voltage for programming according to a programming pulse number at the moment the verifying process passes in the preceding programming.

### FIELD OF THE INVENTION

The present invention relates to an electrically rewritable non-volatile semiconductor memory device (EEPROM), such as a flash memory, etc, and write-in method thereof.

### BACKGROUND

A NAND type non-volatile semiconductor memory device (see non-patent documents 1-4) is well known for those skilled in art, which comprises a plurality of memory cell transistors (or so-called memory cells below) connected to between bit lines and source lines forming a NAND string and realizes highly integrating.

For common NAND type non-volatile semiconductor memory devices, when erasing, high voltage, for example 20V, is applied to a semiconductor substrate thereof and no voltage, for example 0V is applied to a word line thereof. Following, electrons are removed form an electric charge storage layer formed by poly-silicon material and so on. The threshold voltage is lower than the erasing threshold value (for example −3V). In the other hand, when writing in (programming), no voltage, for example 0V is applied to a semiconductor substrate thereof and high voltage, for example 20V, is applied to a controlling gate thereof. Following, electrons are injected from the semiconductor substrate to the floating gate. The threshold value is higher than the write-in-threshold value (for example 1V). The memory cell to get these threshold values can determine the state by applying a readout voltage (for example 0V) between the write-in threshold value and the readout threshold value to the control gate and identifying if the current is flowing through the memory cell.

Within the non-volatile semiconductor memory device formed as above, when write-in to the memory cell, which is a write-in target, is proceeding by a programming action, electrical charges are injected into the floating gate of the memory cell transistor and the threshold voltage rises. Thus even though voltage, which is below the gate threshold voltage, is applied, there are no currents flowing through. The state after writing-in data “0” is then accomplished. Commonly, the threshold voltages on erasing state are not uniform. Therefore, If applying a determined write-in voltage for carrying out the programming action and verifying the threshold voltage so as to be higher than verify-level, the threshold voltages of the memory cell after writing-in will have distribution higher than verify-level.

In the case of the non-volatile semiconductor memory device of multi-valued memory cells, wherein the memory cells are set different threshold voltages to perform multi-values, if the threshold voltages have wide distribution, the interval between adjacent level values will become narrow so that faithful data saving will also become difficult. To solve this problem, patented document 5 discloses a non-volatile memory core circuit, which stores multi-values by setting plural and different threshold voltages to the memory cell, and a control circuit, which controls write-in to the memory core circuit. When programming the memory cell to one threshold voltage, the control circuit programs a memory cell to be set that threshold voltage and a memory cell to be set a threshold voltage higher than that threshold voltage to that threshold voltage. The control circuit begins to program from the lowest threshold voltage among the plural and different voltages in order.

Additionally, a non-volatile semiconductor memory device is proposed in patented document 6 to improve programming accuracy of the non-volatile semiconductor memory and decrease programming time as well. When programming data to the non-volatile memory cell the non-volatile semiconductor memory increases a programming voltage slowly and in the meantime applies the programming voltage to the memory cell many times. At this time, the increment of the programming voltage is set to be a first voltage before the threshold voltages of all of the memory cell to be written-in reach a initial value. After that, the increment of the programming voltage is set to be a second voltage before the threshold voltages reach a target value. Because of increasing the programming voltage without changing the increment, the threshold voltage of the memory cell can approach the target value with few programming pulses. However, by setting the increment of the programming voltage to be the second voltage after the threshold voltage passes through the initial value, the error to the target value of the threshold voltage can be limited within minimum range. As a result, the programming time of the memory cell can reduce.

Additionally, a non-volatile semiconductor memory device proposed in patented document 7 can appropriately set the initial value of the control gate voltage and the increment of the control gate voltage during the stage proceeds so as to make each state of the stage that write-in ends different, and can control the threshold voltage accurately. The non-volatile semiconductor memory device is provided with memory cell arrays and control circuits. In a write-in action, a voltage applying process and a verifying process are carried out repeatedly. The voltage applying process is setting the control gate voltage which is going to applied to the control gate of the memory cell of the write-in target and corresponds to each write-in state, so that the voltage difference between each write-in state of the control gate voltage becomes equal to the voltage difference between each write-in state of the threshold voltage, which is used to determine the each write-in state, and then applying the control gate voltage corresponding to the write-in state to the unwritten-in memory cell. The verifying process is determining if the threshold voltage of the memory cell is within the threshold voltage range of corresponding write-in state.

Patent document 1 JP H09-147582;
Patent document 2 JP 2000-285692;
Patent document 3 JP 2003-346485;
Patent document 4 JP 2001-028575;
Patent document 5 JP 2001-325796;
Patent document 6 JP 2003-173688; and
Patent document 7 JP 2007-193885.

### Problems to be Solved

FIG. 4 shows probability distribution of threshold voltages (Vt distribution) of an MLC (Multi Level Cell) flash cell according to the prior art. FIG. 5 shows a state diagram of the moment when programming from state (10L) to state (00) based on the probability distribution of threshold voltages (Vt distribution) in FIG. 4. In the prior art, the case of a flash memory with four value is shown. As an example shown in FIG. 4, the states (11), (01), (00), and (10) are arranged orderly, which start from the lowest threshold voltage. Furthermore, (10L) is the state when programming LSB (the lowest bit), and (10U) is the state after programming MSB (the highest bit). R1 is readout voltage; V_{PV}1 is verifying voltage of the state (01); V_{PV}2 is verifying voltage of the state (00); and V_{PV}3 is verifying voltage of the state (10U).

FIG. 6 shows a write-in voltage over time diagram of the period when programming the state (10) after programming the state (00) by ISPP (Increment Step Pulse Program) method according to the prior art. In FIG. 6, when programming of the state (00), five programming pulses 101-105 are used and verifying process 111-115 proceeds right after applying those pulses. Additionally, when programming of the state (10), five programming pulses 201-205 are used and verifying process 211-215 proceeds right after applying those pulses.

In FIG. 4, arrows 301, 302 show the occasions of programming a memory cell from the state (10L) (LSB programming state) to the state (10U) (MSB programming state) and state (00), respectively. The latter occasion as shown in FIG. 5 is that the initial programming pulse makes the cell distribution move toward the higher threshold voltage. Then the next increased programming pulse can narrow the distribution of the threshold voltage by the ISPP method. Therefore, it is a common idea that maintaining the initial programming pulse in the lowest voltage as far as possible is preferred. However, this method has restrictions because performance of the memory cell degrades in some cases.

Degradation of the memory cell directly affects the performance of write-in speed. If the memory cell degrades, more ISPP steps are needed so as to make the threshold voltage distribution of all of the memory cells to be programmed reach the preferred situation. Therefore, more time is needed to move the threshold voltage distribution.

FIG. 7 shows a write-in voltage over time diagram, wherein more than one step and additional time are needed in order to program the state (00) according to the prior art. The symbol in FIG. 7 is the same as that in FIG. 6. Because the initial voltage for the initial programming pulse is not changed, the degradation of the memory cell directly affects the write-in speed. Finally, the write-in speed is determined by specification so the required time becomes longer and the possibility of that the write-in action fails becomes higher.

FIG. 8 shows a flowchart representing an example of a programming process according to the prior art. In FIG. 8, a predetermined programming voltage Vstartdef (n) is set at step Si and the programming voltage Vstartdef (n) is set to be a programming voltage Vpgm (n) at step S2. A programming pulse having the programming voltage Vpgm (n) is applied at step S3 and whether programmed or not is verified at step S4. It is judged whether all of the memory cells have passed or not at step S5, and then the programming process goes to step S7 if yes or goes to step S6 if no. The programming voltage Vpgm (n) is added by the increment Vstep and set to be the programming voltage Vpgm (n) again at step S6 and then the programming process proceeds back to step S3.

Next, a predetermined programming start voltage Vstartdef (n+1) is set at step S7 and the programming start voltage Vstartdef (n+1) is set to be a programming voltage Vpgm (n+1) at step S8. A programming pulse having the programming voltage Vpgm (n+1) is applied at step S9 and whether programmed or not is verified at step S10. It is judged whether all of the memory cells have passed or not at step S11, and then the programming process finishes and the next predetermined process proceeds if yes or the programming process goes to step S12 if no. The programming voltage Vpgm (n+1) is added by the increment Vstep and set to be the programming voltage Vpgm (n+1) again at step S12 and then the programming process proceeds back to step S3.

Within the programming process of FIG. 8, the process from step S1 to step S6 is a process used for programming from a state to another state which has higher threshold voltage (ex. from the state (10L) to the state (00)). The process from step S7 to step S12 is a process used for programming from a state to another state which has higher threshold voltage (ex. from the state (10L) to the state (10U)).

The above flowchart shows an example of possibility of how the programming process fails when using ISPP method according to the prior art. If programming the state (00) needs more than 6 pulses, the required additional time due to programming the degraded cell can not recover and the storage becomes a fail.

That is, within the MLC type flash memory according to the prior art, programming algorithm is formed by successively combining the programming pulse and the verifying step. If a verifying process fails, a voltage higher than the previous pulse voltage is applied to the memory cell through the word line. Thus, the verifying step repeatedly proceeds until all memory cells to be programmed pass in the verifying process. The process is the so-called ISPP method.

Because of passing through an erasing or write-in cycle many times and dispersion of the process, many verifying processes change. If the number of times of the verifying process increases, the speed of the memory write-in will decline and finally deviate from the specification value.

The purpose of this invention is to provide a non-volatile semiconductor memory device and write-in method thereof, which solves the above problems and decrease the number of times of the verifying process for shortening the time to program.

### Means for Solving the Problems

The non-volatile semiconductor memory device concerning the first invention, comprising:
a non-volatile memory array, which stores multi-valued states by setting a plurality of different threshold voltages corresponding to a plurality of states to each memory cell; and
a control circuit, which controls programming to the memory cell array,
wherein when increasing a programming voltage from a predetermined programming start voltage by a predetermined voltage increment gradually and verifying it at the same time for programming the memory cell, the control circuit determines and sets the programming start voltage for programming according to a programming pulse number at the moment the verifying process passes in the preceding programming.

In the non-volatile semiconductor memory device, the programming pulse number at the moment the verifying process passes is a programming pulse number at the moment programming ends.

Herein, the control circuit determines the programming start voltage according to a difference between the programming pulse number at the moment programming ends and a predetermined definition value.

Further, in the non-volatile semiconductor memory device the programming pulse number at the moment the verifying process passes is a programming pulse number at the moment initial programming passes.

Herein, the control circuit determines the programming start voltage according to a difference between the programming pulse number at the moment initial programming passes and a predetermined definition value.

Moreover, in the non-volatile semiconductor memory device, the control circuit determines and sets the programming start voltage according to the programming pulse number at the moment programming ends and the programming pulse number at the moment initial programming passes.

A write-in method for a non-volatile semiconductor memory device concerning the second invention, wherein the non-volatile semiconductor memory device comprises:
a non-volatile memory array, which stores multi-valued states by setting a plurality of different threshold voltages corresponding to a plurality of states to each memory cell; and
a control circuit, which controls programming to the memory cell array,
the write-in method for a non-volatile semiconductor memory device, comprising:
when increasing a programming voltage from a predetermined programming start voltage by a predetermined voltage increment gradually and verifying it at the same time for programming the memory cell, determining and setting the programming start voltage for programming according to a programming pulse number at the moment the verifying process passes in the preceding programming.

Further, in the write-in method for a non-volatile semiconductor memory device, the programming pulse number at the moment the verifying process passes is a programming pulse number at the moment programming ends.

Herein, programming comprises determining the programming start voltage according to a difference between the programming pulse number at the moment programming ends and a predetermined definition value.

Further, in the write-in method for a non-volatile semiconductor memory device, the programming pulse number at the moment the verifying process passes is a programming pulse number at the moment initial programming passes.

Herein, programming comprises determining the programming start voltage according to a difference between the programming pulse number at the moment initial programming passes and a predetermined definition value.

Moreover, in the write-in method for a non-volatile semiconductor memory device, programming comprises determines and sets the programming start voltage according to the programming pulse number at the moment programming ends and the programming pulse number at the moment initial programming passes.

Therefore, according to the non-volatile semiconductor memory device and the write-in method thereof concerning the invention, when increasing the programming voltage from a predetermined programming start voltage by a predetermined voltage increment gradually and verifying it at the same time, the non-volatile semiconductor memory device determines and sets the programming start voltage for programming according to programming pulse number passing the verifying process in the preceding programming. Therefore, the yield rate of the memory array and the lifetime of the memory cell can increase by using dynamic adjusting of the programming voltage which is used in the programming action with dependence on the process number of verifying. By this device and method, for the cell which showing a feature “slower programming”, the programming voltage can dynamically increase only in the necessary case. Therefore, the number of times of the verifying process decreases and the time to program can be shortened.

### THE BEST EMBODIMENTS FOR IMPLEMENTING THE INVENTION

The embodiments of the invention are described below with the drawings. The same element in each embodiment below is marked as the same symbol.

FIG. 1 shows a block diagram of the configuration for a NAND type flash memory EEPROM according to an embodiment of the invention. FIG. 2 shows a circuit diagram of the configuration for the memory cell array 10 and the peripheral circuits in FIG. 1. FIG. 3 shows a circuit diagram of a detailed configuration for a page buffer (corresponding to 2 bit lines) in FIG. 2. First, the configuration for the NAND type flash EEPROM of Embodiment is described below.

In FIG. 1, the configuration for the NAND type flash EEPROM of the embodiment comprises a memory cell array 10, a control circuit 11 for controlling the action thereof, a row decoder 12, a high voltage generating circuit 13, a data rewriting and reading-out circuit 14, a column decoder 15, a command register 17, an address register 18, an action logic controller 19, a data input/output buffer 50, and a data input/output terminal 51.

In the memory cell array 10 as shown in FIG. 2, a NAND cell NU (NU0, NU1, . . . ) is configured by series connection of 16 stack-gate structured electrically rewritable non-volatile memory cells MC0˜MC15. The drain end of each NAND cell NU is coupled to a bit line BL through a selective gate transistor SG1 and the source end of the same is coupled to a common source line CELSRC. The control gates of the memory cells MC arranged in the row directions are coupled to a common word line, and the gates of the selective transistor SG1, SG2 are coupled to the selective gate lines SGD, SGS arranged parallel to the word lines WL. One page, which is a unit of write-in or readout, is a range of the selected memory cell through one word line WL. One block, which is a unit of data erasing, is a range of a plurality of NAND cells NU of one page or its integer multiples. In order to carry out rewriting and reading of the data of the page unit, the rewriting and reading-out circuit 14 comprises a sense amplifier circuit (SA) and a latch circuit (DL), or so-called a page buffer.

The memory cell array 10 of FIG. 2 can have a simplified structure wherein a plurality of bit lines can share a page buffer. In this case, when writing in or reading out data, the number of bit lines which selectively connected to the page buffer is a unit of one page. FIG. 2 shows the range of the cell array within which data is inputted or outputted with one data input/output terminal 51. In order to select the word line WL of the memory cell array 10 and the bit line BL, the row decoder 12 and the column decode 15 are arranged respectively. The control circuit 11 carries out sequence control of data writing in, erasing, and reading out. The high voltage generating circuit 13 which is controlled by the control circuit boosted generates a high voltage or a middle voltage used for data writing in, erasing, and reading out.

The input/output buffer 50 is used for input/output of data and output of address signals. That is, data is transmitted between the input/output terminal 51 and the page buffer 14 through the input/output buffer 50 and the data line 52. The address signals inputted from the input/output terminal 51 are stored in the address register 18 and sent to the row decoder 12 and the column decoder 15 for decoding. The control command is also inputted from the input/output terminal 51. The inputted command is stored in the command register 17 after decoded and herewith the control circuit 11 is controlled. Such as chip enable signals CEB, command latch enable signals CLE, address latch enable signals ALE, write-in enable signals WEB, readout enable signals REB, and so on, the external control signals are taken out by the action logic controller 19, and the inner control signals corresponding to an action mode are generated. The inner control signals are used to control data latching or transmitting on the input/output buffer 50. Following, the data is transmitted to the control circuit 11 for action controlling.

The page buffer 14 has two latch circuits 14a, 14b, the structure of which is capable of carrying out switching between multi-valued action function and cache function. That is, when one memory cell memorizes two value data of one bit, cache function is provided and when one memory cell memorizes four value data of two bits, cache function is provided and cache function is still effective even though limited by address. The detailed configuration for the page buffer 14A (corresponding to 2 bit lines) for implementing the function is shown in FIG. 3.

In FIG. 3, the configuration for the page buffer 14A comprises a latch L1 formed by 2 inverters 61, 62, a latch L2 formed by 2 inverters 63, 64, a verifying capacitor 70, a pre-charging transistor 71, verifying transistors 72-75, verifying and pass/fail-judging transistors 76, 77, column gate transistors 81, 82, transmitting switch transistors 83-85, 88, 89, bit line selecting transistors 86, 87, a latch equalizing transistor 90, a reset transistor 91.

In FIG. 3, 2 bit lines BLe, BLo are selectively coupled to the page buffer 14A. In this case, the bit line selecting transistors 86, 87 are conductive by the bit line selecting signal BLSE or BLSO, and one of the bit lines BLe, BLo is selectively coupled to the page buffer 14A. Note that when a bit line is selected, it is preferred that the other bit line which is not selected is set at fixed ground level or voltage to reduce noises between adjacent bit lines.

The page buffer 14A of FIG. 3 is provided with a first latch L1 and a second latch L2. The page buffer 14A mainly manages readout and write-in actions according to predetermined action control. The second latch L2 is a secondary latch circuit realizing cache function in a 2-valued action. In the case that cache function is not used, the second latch L2 assists the action of the page buffer 14A and realizes multi-valued actions.

The latch L1 is configured by parallel connection of clocked inverters 61, 62. The bit line 10 of the memory cell array 10 is coupled to a sense node N4 via the transmitting switch transistor 85, and the sense mode N4 is coupled to a data holding node N1 of the latch L1 via the transmitting switch transistor 83. The sense node N4 is provided with the pre-charging transistor 71. The node N1 is coupled to a temporally-memorizing node N3, which is used to temporally memorize the data of the node N1, via the transmitting switch transistor 74, 75. The node N4 is coupled to the pre-charging transistor 71, which is used to pre-charge a voltage V1 to the bit line. The node is coupled to the capacitor, which is used to maintain voltage levels thereof. The other terminal of the capacitor 70 is coupled to the ground.

The second latch L2 is configured by parallel connection of clocked inverters 63, 64 as well as the first latch L1. Two data nodes N5, N6 of the latch L2 are coupled the data line 52, which is coupled to the data input/output buffer 50, via the column gate transistors 81, 82, which are controlled by a column selecting signal CSL. The node N5 is coupled to the node N4 via the transmitting switch transistor 84.

FIG. 3 shows the connection of the memory array cell 10, the page buffer 14, and the data input/output buffer 50. A processing unit of the readout and write-in of the NAND type flash EEPROM is volume of one page simultaneously selected at a row address (for example 512 bytes). Because there are 8 data input/output terminal 51, each data input/output terminal 51 transmits 512 bits. FIG. 3 shows the configuration corresponding to 512 bits.

In the case that data are written-in to the memory cell, the programming data is taken in the second latch L2 from the data line 52. The programming data must be at the latch L1 for starting the programming action, therefore the data held by the latch L2 are transmitted to the latch L1 subsequently. In the readout action, the readout data must be at the latch L2 for being outputted from the data input/output terminal 51, therefore the data readout by the latch L1 needs to be transmitted to the latch L2. Consequently, the configuration can make data be transmitted between the latch L1 and the latch L2 by conducting the transmitting transistors 83, 84. At this time, a latch circuit which is a destination is switched to on an inactive state and transmitting the data, and then the latch circuit which is a destination is switched back to on an active state holding the data.

In FIG. 1-FIG. 3, the basic action of writing-in or erasing data to the memory cell 10 is prior art, which is disclosed by, for example, non-patented documents 4-5. The detailed description is omitted.

In the flash EEPROM of the embodiment, the improved ISPP method which can reduce the number of verifying operations and decrease the time for programming is proposed.

FIG. 9 shows a flowchart for an example of a programming process according to an embodiment. The programming process of FIG. 9 is a process proceeding in each word line. In comparison with the programming action according to the prior art of FIG. 8, steps S21, S22, and S23 are added and the step S7 is changed to a step S7A. In the embodiment, the feature of the control circuit 11 is, for programming to the memory cell, adding the programming voltage by a predetermined voltage Vstep sequentially and performing the verifying operation in the meantime when programming the memory cell from the state (11) to the state (01) (or, for example programming from the state (10L) to the state (00)); basing on the number of times of all memory cells passing the verifying process (the example in FIG. 9 is a programming pulse number Npactlast(N)) setting a programming start voltage Vstart(n+1) (=Vstartdef(n+1)+Δ (Npactlast(n)), Δ (Npactlast(n)) means an increment voltage according to the programming pulse number Npactlast(n)) for programming to the state, for example (10U); and adding the programming start voltage Vstart(n+1) by a predetermined voltage Vstep sequentially and performing the verifying operation in the meantime for programming to the state, for example (10U).

In FIG. 9, the predetermined programming start voltage Vstartdef (n) is set at step S1 and a parameter Npact (n) which counts the pulse number is formatted to 1. The programming voltage Vstartdef (n) is set to be a programming voltage Vpgm (n) at step S2. Then a programming pulse having the programming voltage Vpgm (n) is applied at step S3 and whether programmed or not is verified at step S4. It f whether all of the memory cells have passed or not at step S5, and then the programming process goes to step S23 if yes or goes to step S6 if no. At step S6, after the programming voltage Vpgm (n) is added by the increment Vstep, the parameter Npact(n) is added by 1 and the programming voltage Vpgm (n) is set. Finally, the programming process proceeds back to step S3.

Next, at step S23, the parameter Npact (n) is set to be the programming pulse number Npactlast which is a programming pulse number when write-in is just over. At step S7A, the programming start voltage Vstart(n+1) is determined and set according to the programming pulse number Npactlast. At step S8, the programming start voltage Vstartdef (n+1) is set to be a programming voltage Vpgm (n+1). Following, a programming pulse having the programming voltage Vpgm (n+1) is applied at step S9 and whether programmed or not is verified at step S10. It is judged whether all of the memory cells have passed or not at step S11, and then the programming process finishes and the next predetermined process proceeds if yes or the programming process goes to step S12 if no. The programming voltage Vpgm (n+1) is added by the increment Vstep and set to be the programming voltage Vpgm (n+1) again at step S12 and then the programming process proceeds back to step S3.

In FIG. 9, for example, when the programming pulse number Npactlast equals 5, the increment voltage Δ (Npactlast(n)) equals 0, and when the programming pulse number Npactlast equals 5, the increment voltage Δ (Npactlast(n)) equals 0.5. If the initial voltage of the programming pulse of the state (10U) can be adjusted, the longer programming time of the state (00) can be recovered. Furthermore, N is stored in an internal memory of the control circuit 11.

FIG. 10 shows a write-in voltage over time diagram of the period when programming the state (10) after programming the state (00) by ISPP (Increment Step Pulse Program) method according to the embodiment. In FIG. 10, a programming start voltage at the moment when programming the state (00) is Vstart2, and then a programming start voltage Vstart3, which is a programming start voltage at the moment when programming the next state (10), is determined and set according to the programming pulse number at the moment when programming of the state (00) passes. The setting is able to set each word line. In order to maintain certain programming time through the life of the memory cell, the programming voltage of the threshold voltage distribution should be dynamically adjusted. If the programming voltage is dynamically adjusted according to the programming pulse which is the result of the ISPP method used at the previous programming action, the entire programming time can be maintained in a specification value. Commonly speaking, the method can also be used for programming of other threshold voltage distribution.

FIG. 11 shows a possibility distribution of threshold voltages (Vt distribution) of a 4-valued flash EEEPROM according to the embodiment. In FIG. 11, V_{PV}1 is the verifying voltage of the state (01); V_{PV}2 is the verifying voltage of the state (00); and V_{PV}3 is the verifying voltage of the state (10U). In the case of a MLC type NAND flash memory in which each memory cell has 2 bits, threshold voltage distribution of 4 states (11), (01), (10), and (00) exists.

In the LSB programming operation of FIG. 11(a), the state (11) is maintained without change, or programmed to the state (10L) by a programming process 401. In the MSB programming operation of FIG. 11(b), the state (11) is maintained without change, or programmed to the state (01) by a programming process 402. Moreover, the state (10L) is programmed to the state (00) by a programming process 403, or programmed to the state (10U) by a programming process 404.

Here auto-adjusting for the programming voltage can be applied to all situations. The previous detailed embodiment is easy to be practiced because that occurs during one MSB action (one user command). Another method for practicing auto-adjusting for the programming voltage is regularly storing the cycle number of verifying programming actions each distribution, and using this data to adjust the programming start voltage of each distribution. Auto-adjusting for the programming voltage can be applied to all threshold voltage distribution of the MLC type NAND flash memory in which a bit memory cell has 2 bits. That is, in this invention, when increasing the programming voltage from a predetermined programming start voltage by a predetermined voltage increment gradually and verifying it at the same time, the non-volatile semiconductor memory device determines and sets the programming start voltage for programming according to a programming pulse number at the moment the verifying process passes in the preceding programming (not limited to the programming just before this). For example, in the programming process 404, it is practicable determining and setting the above programming start voltage for programming according to the programming pulse number at the moment the verifying process passes in any of the programming processes 401-403.

### CONCLUSION OF EMBODIMENT

As described above, programming for “slow” cells makes programming performance overly degraded because the cycle number of programming and verifying increases. To prevent this situation, auto-adjusting for the programming voltage is used. That is, in the case that the state (00) is programmed initially in the MLC distribution using Gray Code, the control circuit 11 stores the cycle number of programming and verifying. When the number exceeds a certain limitation, the programming start voltage for programming the state (10) should be increased. This mechanism is used to gradually reduce the cycle of programming and verifying for programming the state (10). Therefore, the entire programming time can be maintained in the case that programming of the state (00) requires a cycle number lower than a certain limitation.

For example, five typical pulses can be used for programming of the state (00) and the state (10). When programming of both states (00) and (10) requires five pulses, which are a maximum, for programming all cells under the fifth distribution which is wished, the programming performance will become worst (near the longest time allowed by the specification) (please refer to FIG. 6).

Following, if the performance of the memory cell decreases due to durability or unevenness of the process, one more programming and verifying cycle is necessary for programming the state (00) (please refer to FIG. 7). However, in order to maintain the programming speed of specification, the sixth programming pulse doesn't pass and the failure happens at the last programming state.

On the other hand, in the case that the control circuit 11 allows six cycles of programming and verifying instead of five cycles which are a maximum, the possibility that programming of the state (00) passes is higher. Then the programming start voltage for programming the state (10) increases so that the cycle number of programming and verifying can reduce to, for example, 4. Therefore, the entire programming time doesn't exceed the specification and the programming pulse can pass at the last state (refer to FIG. 10).

The write-in method according the embodiment shows that the yield rate of the memory array and the lifetime of the memory cell increases by using dynamic adjusting of the programming voltage which is used in the programming action with dependence on the process number of verifying. By this method, for the cell which showing a feature “slower programming”, the programming voltage can dynamically increase only in the necessary case.

### Modified Example

Regarding the above embodiment, in the programming process proceeding for each word line, the programming start voltage Vstart (n+1) is determined and set according to the programming pulse Npactlast which is at the moment when programming ends (YES at the step S5 in FIG. 9). However the invention is not limited in this, as a modified example shown in FIG. 13, the programming start voltage Vstart (n+1) also can be determined and set according to the programming pulse number at the moment initial programming passes Npactfirst (n) (is counted by the step S31 and S32 of FIG. 13) and the programming pulse number at the moment programming ends Npactlast (n) (refer to the step S7B in FIG. 13). In the case that the unevenness of the manufacture is serious, the programming voltage can be adjusted appropriately. The detail about this case is described later.

Many kinds of examples of the programming start voltage Vstart (n+1) according to the embodiment and the modified example are described below.

[chart1]

An example for the definition and value of each parameter

Verifying voltage on the nth state (setting value) Vpv (n)=0.5V;
Programming start voltage on the nth state (setting value) Vstartdef (n)=16.5V ;
Verifying voltage on the n+1th state (setting value) Vpv (n+1)=2.0V;
Programming start voltage on the n+1 th state (setting value) Vstartdef (n+1)=18.0V;
Voltage increment (setting value) Vstep=0.4V ;
Programming pulse number on the nth state (definition value at the moment programming ends) Npdeflast (n)=12;
Programming pulse number on the nth state (definition value at the moment initial programming passes) Npdeffirst (n)=3;
Programming pulse number on the nth state (actual value at the moment programming ends) Npactlast (n)=14;
Programming pulse number on the nth state (actual value at the moment initial programming passes) Npactfirst (n)=4;
(Annotation) an example of the states:
The first state=state (01), the second state=state (00).

### Embodiment 1

The programming start voltage, in the case where each state has a definition value of the programming pulse number, is shown in the following formula.

Vstart(n+1)=Vstartdef(n+1)+[Npactlast(n)Npdeflast(n)−0.5]×Vstep [Formula 1]

An example with values of Embodiment 1 is shown in the next formula.

Vstart(n+1)=18+(14−12−0.5)×0.4=18.6 (V) [Formula 2]

In Embodiment 1, with regard to the page buffer 14 or the memory block of which the action speed is slightly slow, the programming voltage will be corrected. Correcting coefficient (−0.5) means it corresponds to a half of the programming pulse for preventing from over correcting.

### Embodiment 2

The programming start voltage, which is figured from the programming pulse number directly, is shown in the following formula.

Vstart(n+1)=Vstart(n)+[Npactlast(n)−Npdeflast(n)−0.5]×Vstep+α×[Vpv(n+1)−Vpv(n)] [Formula 3]

α is a predetermined constant, for example, 1.4. An example with values of Embodiment 2 is shown in the next formula.

$$\begin{matrix}Vstart ( n + 1 ) = 16.5 + ( 14 - 12 - 0.5 ) \times \\ 0.4 + 1.4 \times ( 2.0 - 0.5 ) \\ = 18.2 ( V )\end{matrix} \qquad [ Formula 4 ]$$

In FIG. 2, the programming voltage is corrected as well as Embodiment 1.

### Embodiment 3

In the case that the programming start voltage is determined according to the programming pulse number at the moment initial programming passes, the programming start voltage, in the case that each state has a definition value of the programming pulse number, is shown in the following formula.

Vstart(n+1)=Vstartdef(n)+[Npactfirst(n)−Npdeffirst(n)−0.5]×Vstep [Formula 5]

An example with values of Embodiment 3 is shown in the next formula.

Vstart(n+1)=18+(5−3−0.5)×0.4=18.6 (V) [Formula 6]

In Embodiment 3, although the programming pulse number at the moment initial programming passes is used in place of the programming pulse number at the moment programming ends to determine the programming start voltage, the result which is the same as Embodiment 1 can be obtained.

### Embodiment 4

In the case where the programming start voltage is determined according to the programming pulse number at the moment initial programming passes, the programming start voltage, which is figured from the programming pulse number directly, is shown in the following formula.

Vstart(n+1)=Vstart(n)+[Npactfirst(n)−Npdeffirst(n)−0.5]×Vstep+α×[Vpv(n+1)Vpv(n)] [Formula 7]

An example with values of Embodiment 4 is shown in the next formula.

$$\begin{matrix}Vstart ( n + 1 ) = 16.5 + ( 5 - 3 - 0.5 ) \times 0.4 + \\ 1.4 \times ( 2.0 - 0.5 ) \\ = 18.2 ( V )\end{matrix} \qquad [ Formula 8 ]$$

In Embodiment 4, although the programming pulse number at the moment initial programming passes is used in place of the programming pulse number at the moment programming ends to determine the programming start voltage, the result which is the same as Embodiment 2 can be obtained.

### Embodiment 5

In FIG. 5, in the case that the increment voltage Vstep is determined according to the programming pulse number at the moment initial programming passes and the programming pulse number at the moment programming ends, the increment voltage is shown in the following formula.

Vstep(n+1)=[Npactlast(n)−Npactfirst(n)]/[Npdeflast(n)−Npdeffirst(n)]×Vstep(n) [Formula 9]

An example with values of Embodiment 5 is shown in the next formula.

Vstep(n+1)=(14−5)/(12−3)×0.4=0.4 [Formula 10]

Therefore, the value which is the same as the setting value Vstep can be obtained.

### Application Example

FIG. 12 shows probability distribution of threshold voltages (Vt distribution) of an 8-valued flash EEEPROM according to the modified example. In FIG. 12, V_{PV}1 is the verifying voltage of the state (011); V_{PV}2 is the verifying voltage of the state (101U); V_{PV}3 is the verifying voltage of the state (001); V_{PV}4 is the verifying voltage of the state (100U); V_{PV}5 is the verifying voltage of the state (000); V_{PV}6 is the verifying voltage of the state (110U); V_{PV}7 is the verifying voltage of the state (010).

In the LSB programming operation of FIG. 12(a), the state (111) is maintained without change, or programmed to the state (110L) by a programming process 501. In the middle bit (means the middle bit between the highest bit and the lowest bit or so-called MIB below) programming of FIG. 12(b), the state (111) is maintained without change, or programmed to the state (101M) by a programming process 502. Moreover, the state (111) is programmed to the state (100M) by a programming process 503, or programmed to the state (110M) by a programming process 504.

In the MSB programming operation of FIG. 12(c), the state (111) is maintained without change, or programmed to the state (011) by a programming process 505. Moreover, the state (101M) is programmed to the state (101U) by a programming process 506, or programmed to the state (001) by a programming process 507. Moreover, the state (100M) is programmed to the state (100U) by a programming process 508, or programmed to the state (000) by a programming process 509. Moreover, the state (110M) is programmed to the state (110U) by a programming process 510, or programmed to the state (010) by a programming process 511.

As shown above, the invention can be applied to a NAND flash memory in which each memory cell has 3 bits. Thus, the density can be increased without increasing the silicon area of the memory array. In this case, threshold voltage distribution of 8 states (111), (110), (100), (101), (001), (011), (001), and (000) exists. In the case that the threshold voltage distribution is changed from 4 values to 8 values (MSB programming), auto-adjusting for the programming voltage can be applied to each distribution with dependence on the previous programming number which is needed. In the case of the MLC type NAND flash memory with 3 bits, more distribution types exist so auto-adjusting for the programming voltage is significant to NAND memory design. That is, in this invention, when increasing the programming voltage from a predetermined programming start voltage by a predetermined voltage increment gradually and verifying it at the same time, the non-volatile semiconductor memory device determines and sets the programming start voltage for programming according to programming pulse number at the moment the verifying process passes in the preceding programming (not limited to the programming just before this). For example, in the programming process 511, it is practicable determining and setting the above programming start voltage for programming according to programming pulse number at the moment the verifying process passes in any of the programming processes 501-510.

In the above embodiment and modified example, the non-volatile memory device is provided with a non-volatile memory cell array, which stores multi-valued states by setting a plurality of different threshold voltages corresponding to a plurality of states to each memory cell; and a control circuit, which controls programming to the memory cell array. The feature of the control circuit is that when increasing the programming voltage from a predetermined programming start voltage by a predetermined voltage increment gradually and verifying it at the same time for programming the memory cell, the control circuit determines and sets the programming start voltage for programming according to a programming pulse number at the moment the verifying process passes in the preceding programming.

A NAND type flash EEPROM is described in the above embodiment, but the invention is not limited thereto and also can be broadly applied to the non-volatile semiconductor memory device which can write-in data to a floating gate of NOR type flash EEPROM and etc. In the above description, the example rewriting is accompanied by the programming speed becomes slow is described, but the speed also could become fast conversely according to the principle of write-in and erasing. The NAND type flash EEPROM is one having the above feature. In the case that the programming becomes fast, if one expects the above situation and doesn't decrease the programming start voltage in advance, the width of the Vth distribution will become wider than the setting one and cause the readout failure happen. Setting the programming start voltage low makes the programming time become longer, so the invention can be applied to shorten the time effectively. When the times of rewriting is few, in contrast to programming begins from a little higher programming start voltage Vstart, the invention is auto-sensing from the actual results that a level has been written and programming the next level from a corrected and a little higher programming start voltage Vstart.

In the above embodiment, it is described supposing the threshold voltage distribution of FIG. 4 and programming the data having the lowest voltage, but the invention is not limited thereto and can be applied to program any data of multi-values.

### POSSIBILITY FOR INDUSTRIAL APPLICATION

As the above detailed description, according to the non-volatile semiconductor memory device and the write-in method thereof concerning the invention, when increasing the programming voltage from a predetermined programming start voltage by a predetermined voltage increment gradually and verifying it at the same time, the non-volatile semiconductor memory device determines and sets the programming start voltage for programming according to a programming pulse number at the moment the verifying process passes in the preceding programming. Therefore, the yield rate of the memory array and the lifetime of the memory cell can increase by using dynamic adjusting of the programming voltage which is used in the programming action with dependence on the process number of verifying. By this device and method, for the cell which showing a feature “slower programming”, the programming voltage can dynamically increase only in the necessary case. Therefore, the number of times of the verifying process decreases and the time to program can be shortened.

### BRIEF DESCRIPTION OF DRAWINGS

FIG. 1 shows a block diagram of the configuration for a NAND type flash memory EEPROM according to an embodiment of the invention.

FIG. 2 shows a circuit diagram of the configuration for the memory cell array 10 and the peripheral circuits in FIG. 1.

FIG. 3 shows a circuit diagram of the detailed configuration for the page buffer (corresponding to 2 bit lines) in FIG. 2.

FIG. 4 shows probability distribution of threshold voltages (Vt distribution) of an MLC (Multi Level Cell) flash cell according to the prior art.

FIG. 5 shows a state diagram of the moment when programming from state (10L) to state (00) based on the probability distribution of threshold voltages (Vt distribution) in FIG. 4.

FIG. 6 shows a write-in voltage over time diagram of the period when programming the state (10) after programming the state (00) by ISPP (Increment Step Pulse Program) method according to the prior art.

FIG. 7 shows a write-in voltage over time diagram, wherein more than one step and additional time are needed in order to program the state (00) according to the prior art.

FIG. 8 shows a flowchart representing an example of a programming process according to the prior art.

FIG. 9 shows a flowchart for an example of a programming process according to an embodiment.

FIG. 10 shows a write-in voltage over time diagram of the period when programming the state (10) after programming the state (00) by ISPP (Increment Step Pulse Program) method according to the embodiment.

FIG. 11 shows a possibility distribution of threshold voltages (Vt distribution) of a 4-valued flash EEEPROM according to the embodiment.

FIG. 12 shows probability distribution of threshold voltages (Vt distribution) of an 8-valued flash EEEPROM according to the modified example.

FIG. 13 show a flowchart for an example of a programming process according to a modified example.

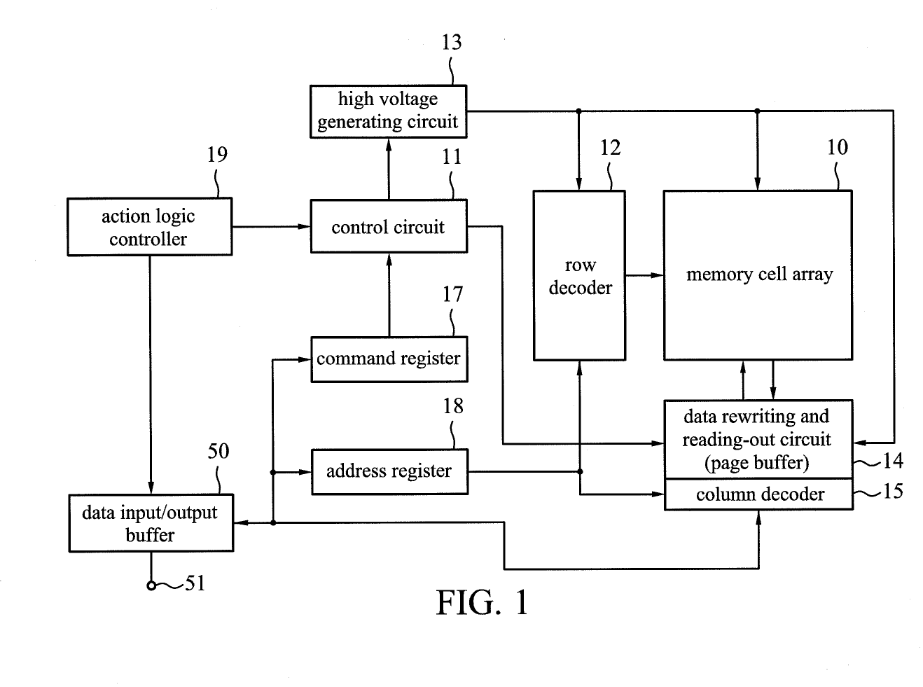

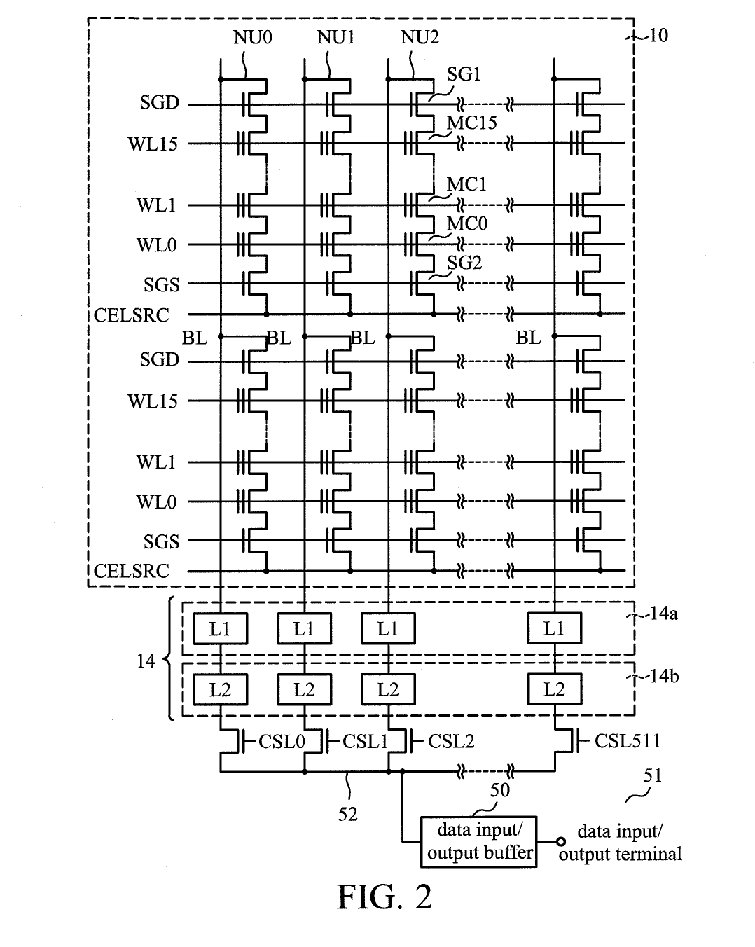

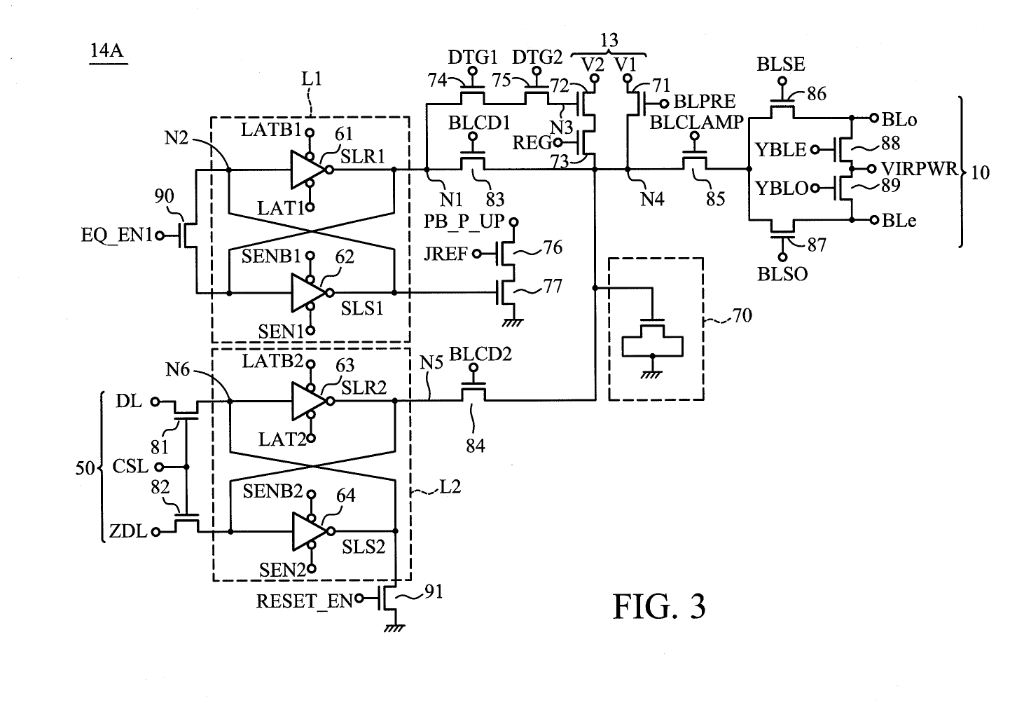

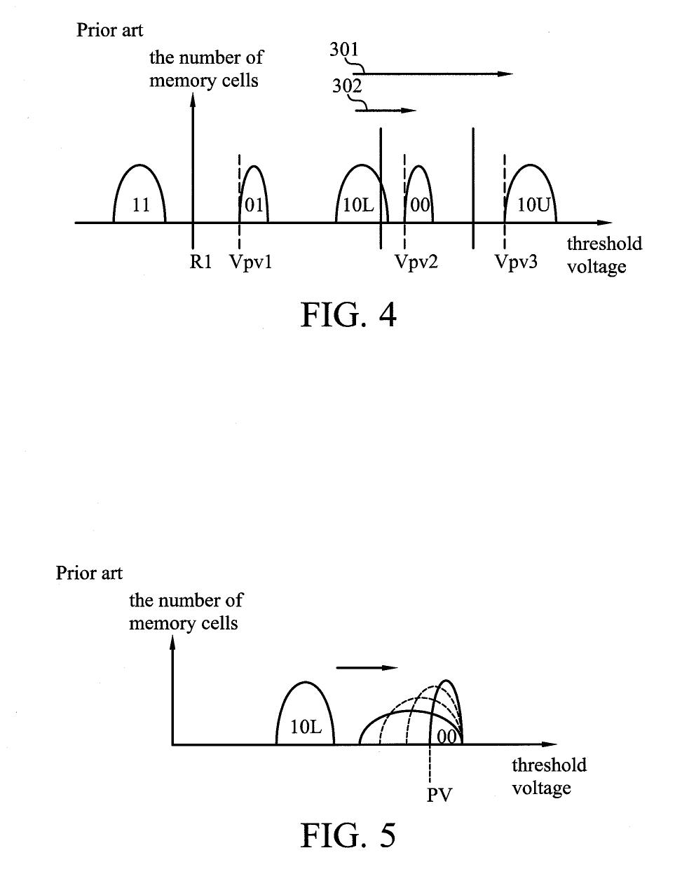

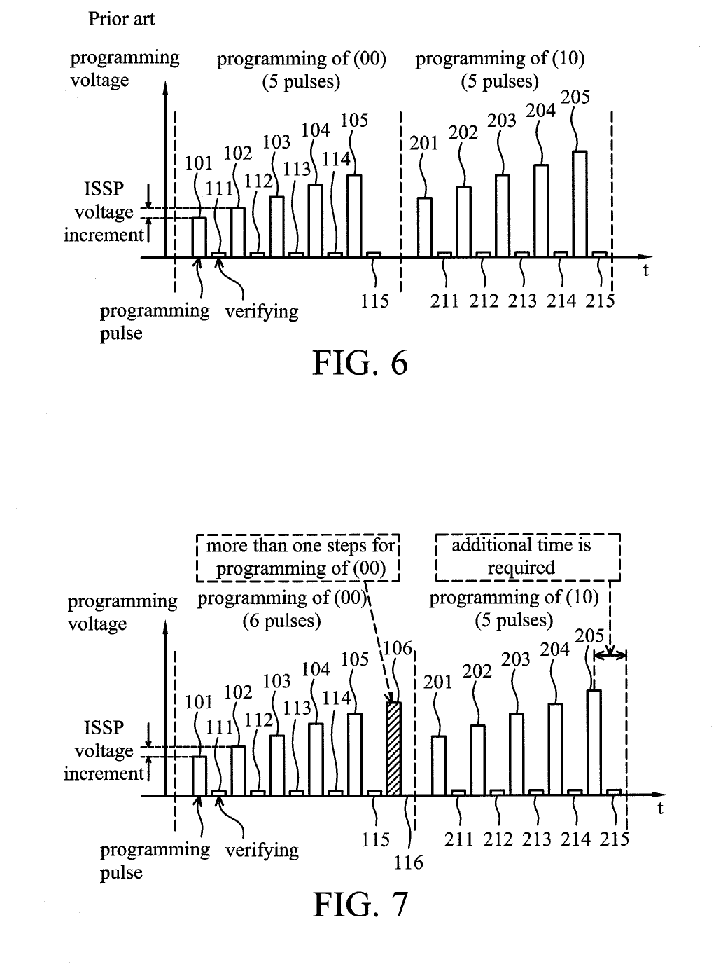

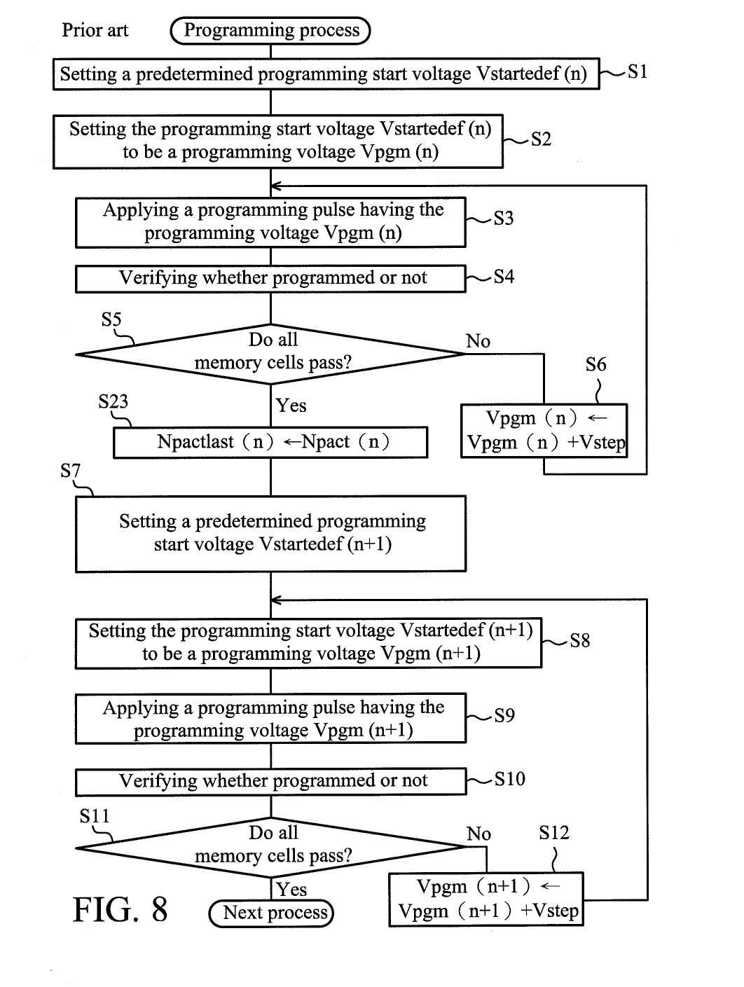

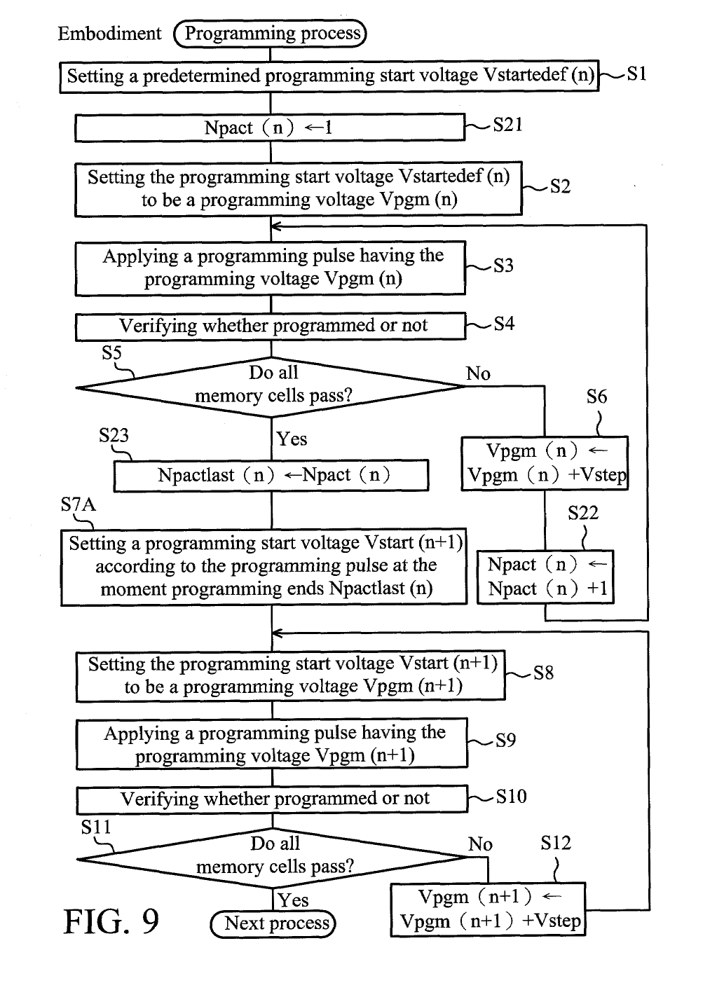

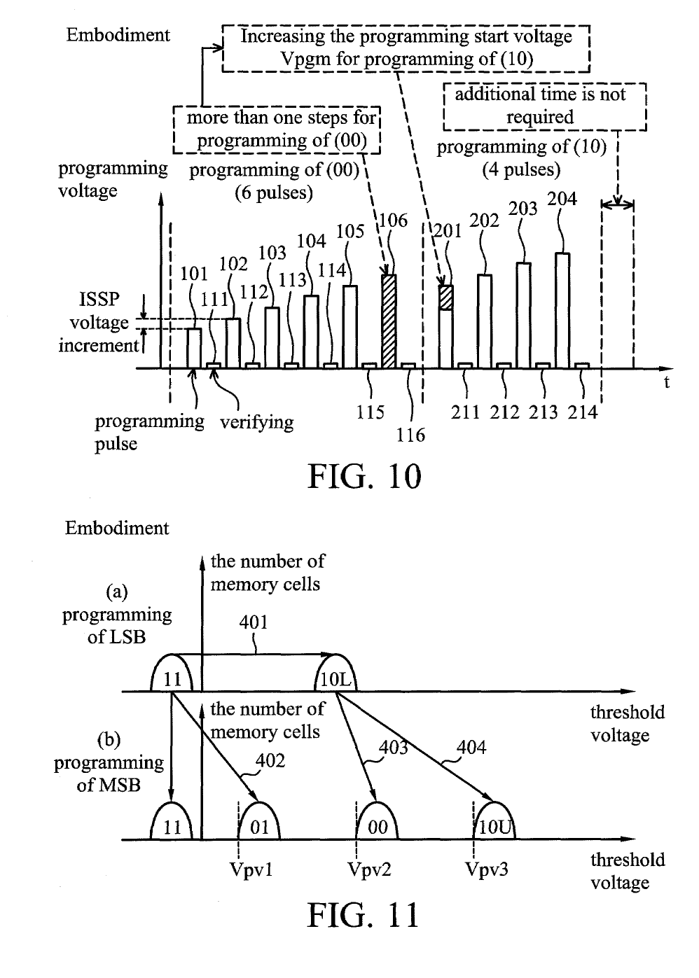

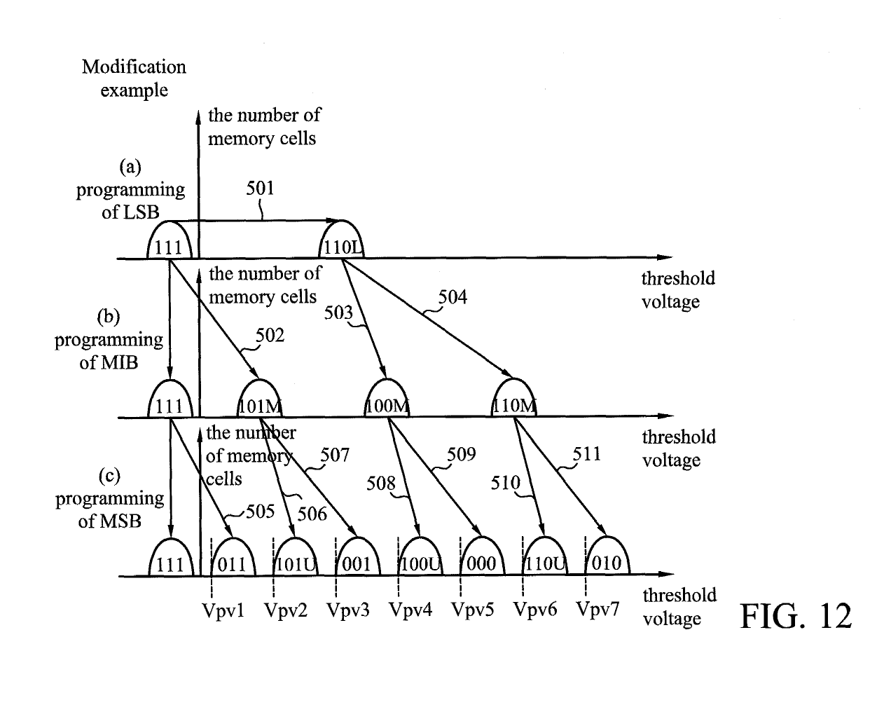

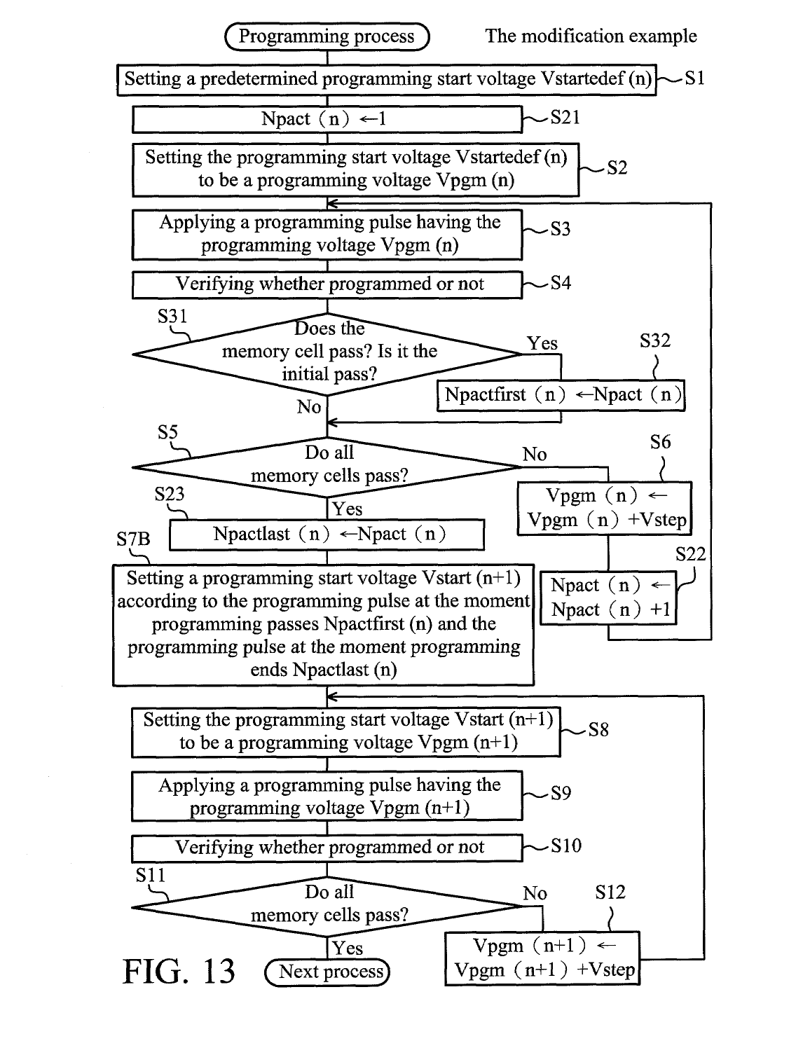

### SYMBOL DESCRIPTION

10 . . . memory cell array,
11 . . . control circuit,
12 . . . row decoder,
13 . . . high voltage generating circuit,
14, 14A . . . data rewriting and reading-out circuit (page buffer),
14a, 14b . . . latch circuit,
15 . . . column decoder,
17 . . . command register,
18 . . . address register,
19 . . . action logic controller,
50 . . . data input/output buffer,
51 . . . data input/output terminal,
52 . . . data line, and
L1, L2 . . . latch.

1. A non-volatile semiconductor memory device, comprising:
a non-volatile memory array, which stores multi-valued states by setting a plurality of different threshold voltages to correspond to a plurality of states to each memory cell; and
a control circuit, which controls programming to the memory cell array,
wherein when increasing a programming voltage from a predetermined programming start voltage by a predetermined voltage increment gradually and verifying it at the same time for programming the memory cell, the control circuit determines and sets the programming start voltage for programming according to a programming pulse number at the moment the verifying process passes in the preceding programming.

2. The non-volatile semiconductor memory device of claim 1, wherein the programming pulse number at the moment the verifying process passes is a programming pulse number at the moment programming ends.

3. The non-volatile semiconductor memory device of claim 2, wherein the control circuit determines the programming start voltage according to a difference between the programming pulse number at the moment programming ends and a predetermined definition value.

4. The non-volatile semiconductor memory device of claim 1, wherein the programming pulse number at the moment the verifying process passes is a programming pulse number at the moment initial programming passes.

5. The non-volatile semiconductor memory device of claim 4, wherein the control circuit determines the programming start voltage according to a difference between the programming pulse number at the moment initial programming passes and a predetermined definition value.

6. The non-volatile semiconductor memory device of claim 1, wherein the control circuit determines and sets the programming start voltage according to a programming pulse number at the moment programming ends and a programming pulse number at the moment initial programming passes.

7. A write-in method for a non-volatile semiconductor memory device, wherein the non-volatile semiconductor memory device comprises:
a non-volatile memory array, which stores multi-valued states by setting a plurality of different threshold voltages corresponding to a plurality of states to each memory cell; and
a control circuit, which controls programming to the memory cell array,
the write-in method for a non-volatile semiconductor memory device, comprising:
when increasing a programming voltage from a predetermined programming start voltage by a predetermined voltage increment gradually and verifying it at the same time for programming the memory cell, determining and setting the programming start voltage for programming according to a programming pulse number at the moment the verifying process passes in the preceding programming.

8. The write-in method for a non-volatile semiconductor memory device of claim 7, wherein the programming pulse number at the moment the verifying process passes is a programming pulse number at the moment programming ends.

9. The write-in method for a non-volatile semiconductor memory device of claim 8, programming comprises determining the programming start voltage according to a difference between the programming pulse number at the moment programming ends and a predetermined definition value.

10. The write-in method for a non-volatile semiconductor memory device of claim 7, wherein the programming pulse number at the moment the verifying process passes is a programming pulse number at the moment initial programming passes.

11. The write-in method for a non-volatile semiconductor memory device of claim 10, programming comprises determining the programming start voltage according to a difference between the programming pulse number at the moment initial programming passes and a predetermined definition value.

12. The write-in method for a non-volatile semiconductor memory device of claim 7, wherein programming comprises determines and sets the programming start voltage according to a programming pulse number at the moment programming ends and a programming pulse number at the moment initial programming passes.
